(19) United States
(12) Patent Application Publication
(10) Pub. No.: US 2006/0226513 A1
(43) Pub. Date: Oct. 12, 2006

(54) Elimination of low frequency oscillations in semiconductor circuitry

(76) Inventors: Masaya Iwamoto, Petaluma, CA (US); Jonathan B. Scott, Santa Rosa, CA (US); Thomas S. Low, Sebastopol, CA (US)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 11/092,530

(22) Filed: Mar. 29, 2005

(51) Int. Cl. H01L 27/082

(52) U.S. Cl. 257/565

(57) ABSTRACT

Low frequency oscillations in a circuit are eliminated. A sub-collector region is formed over a semi-insulator region. Bipolar transistor circuitry is formed over the sub-collector region. The bipolar transistor circuitry includes a collector. Voltage at the semi-insulator region is controlled so that voltage at the semi-insulator region is approximately equal to voltage on the collector.

### BACKGROUND

In some semiconductor circuits, oscillatory leakage currents, often called low frequency oscillations (LFOs), can occur in the presence of critical electric fields across the substrate material. For example, LFOs can affect the output signal of a heterojunction bipolar transistor (HBT) implemented using III-V compound semiconductor material. LFOs give rise to signals typically in the range of tens of Hertz to tens of kilohertz. LFOs may appear as tones or local regions of high noise floor. LFOs show a characteristic dependence in frequency with changes in temperature. LFOs are sensitive to electric field, and may appear only at certain field strengths and certain temperatures. LFOs can interfere with wanted signals.

A common way to reduce circuit susceptibility to LFOs involves placing a physical barrier to charge flow between substrate and epitaxial layers during wafer growth. See for Example U.S. Pat. No. 6,528,829 by Gutierrez-Aitken et al. for INTEGRATED CIRCUIT STRUCTURE HAVING A CHARGE INJECTION BARRIER. The physical barrier to charge flow can reduce the charge flow within which LFOs are set up. However, these physical barriers require additional wafer growth steps. The physical barriers typically attenuate, but do not always eliminate LFOs. Imprecise control of composition leads to occasional failure of the physical barrier to suppress LFOs.

### SUMMARY OF THE INVENTION

In accordance with an embodiment of the present invention, low frequency oscillations in a circuit are eliminated. A sub-collector region is formed over a semi-insulator region. Bipolar transistor circuitry is formed over the sub-collector region. The bipolar transistor circuitry includes a collector. Voltage at the semi-insulator region is controlled so that voltage at the semi-insulator region is approximately equal to voltage on the collector.

### BRIEF DESCRIPTION OF THE DRAWINGS

FIG. 1 shows use of an insulating epoxy to eliminate low frequency oscillations in accordance with an embodiment of the present invention.

FIG. 2 illustrates control of backside potential to eliminate low frequency oscillations in accordance with another embodiment of the present invention.

FIG. 3 shows placement of an insulator between backside metal and substrate to eliminate low frequency oscillations in accordance with another embodiment of the present invention.

FIG. 4 also shows placement of an insulator between backside metal and substrate to eliminate low frequency oscillations in accordance with another embodiment of the present invention.

FIG. 5 shows selective patterning of backside metal to eliminate low frequency oscillations in accordance with another embodiment of the present invention.

FIG. 6 also shows selective patterning of backside metal to eliminate low frequency oscillations in accordance with another embodiment of the present invention.

### DESCRIPTION OF THE EMBODIMENT

In accordance with various embodiments of the present invention, backside bias control is used to eliminate low frequency oscillations (LFOs) in semiconductor circuitry. Eliminating LFOs through controlling backside bias control allows for additional processing to be performed on the backside, rather than the front side of a wafer. No additional epitaxial layers are required.

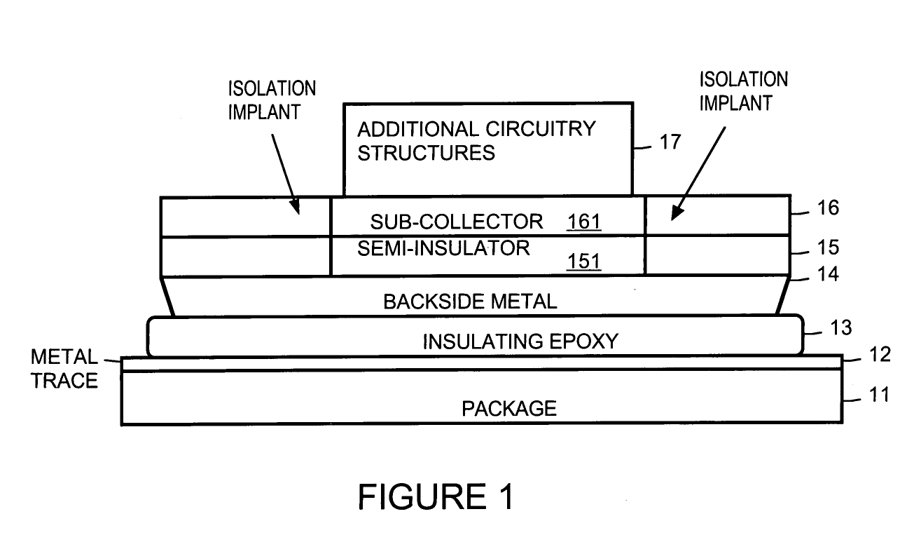

For example, FIG. 1 shows a package 11 having a metal trace 12. Metal trace 12 is, for example, composed of gold, copper or some other metal.

A substrate includes a semi-insulating layer 15. A sub-collector is defined by a layer 16. For example, semi-insulating layer 15 is composed of Gallium-Arsenide (GaAs). Alternatively, semi-insulating layer 25 can be composed of indium-phosphide (InP) or any other substrate where oscillatory leakage currents might occur. Sub-collector layer 16 is highly doped for use as a sub-collector region of, for example, a bipolar transistor. For example, sub-collector layer 16 is formed using standard methods of growing epitaxial layer material. Additional circuitry structures 17 are formed over sub-collector layer 16, dependent upon implementation of a desired circuit functionality. For example, the additional circuitry structures implement a bipolar transistor that has a collector, base and emitter. For example, the additional circuitry structures can include one or more base regions, one or more collector regions and one or more emitter region when a bipolar transistor is implemented. Isolation implants are used to isolate a sub-collector region 161 and a semi-insulator region 151 directly below additional circuitry structures 17. Backside metal 14 is placed on a backside of the substrate.

LFOs can be caused when a critical electric field is applied across semi-insulator region 151. In order to eliminate LFO currents, an insulating epoxy 13 is used to attach package 11 to backside metal 14. For example, insulating epoxy 13 is thermally conducting. Insulating epoxy 13 electrically isolates metal trace 12 from backside metal 14. As a result sub-collector region 161, semi-insulator region 151 and backside metal 14 all float at the collector voltage. This eliminates the electric field across semi-insulator region 151 and thus the LFO current generated in semi-insulator region 151.

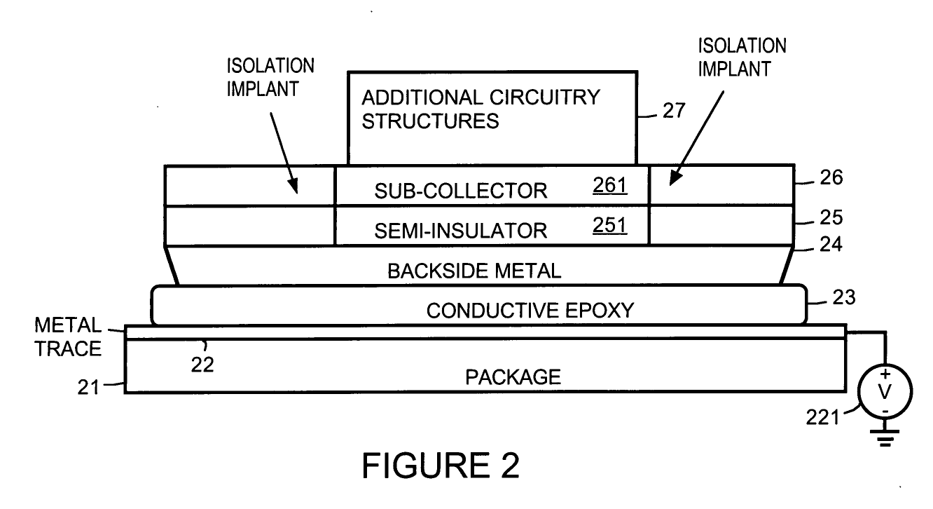

FIG. 2 illustrates an alternative embodiment of the present invention. In FIG. 2, a package 21 has a metal trace 22. Metal trace 22 is, for example, composed of gold, copper or some other metal.

A substrate includes a semi-insulating layer 25. A sub-collector is defined by a layer 26. For example, semi-insulating layer 25 is composed of Gallium-Arsenide (GaAs). Alternatively, semi-insulating layer 25 can be composed of indium-phosphide (InP) or any other substrate where oscillatory leakage currents might occur. Sub-collector layer 26 is highly doped for use as a sub-collector region of, for example, a bipolar transistor. Additional circuitry structures 27 are arranged over sub-collector layer 26, dependent upon implementation of a desired circuit functionality. For example, the additional circuitry structures can include one or more base regions, one or more collector regions and one or more emitter region when a bipolar transistor is implemented. Isolation implants are used to isolate a sub-collector region 261 and a semi-insulator region 251 directly below additional circuitry structures 27. Backside metal 24 is placed on a backside of the substrate.

A conductive epoxy 23 is used to attach package 21 to backside metal 24. Conductive epoxy 23 electrically connects metal trace 22 to backside metal 24. In order to eliminate LFO current generation in semi-insulator region 251, an external voltage supply 221 places a bias on metal trace 22. The bias is kept close to the voltage potential on sub-collector region 261, thereby eliminating LFOs caused by an electric field across semi-insulator regions 251.

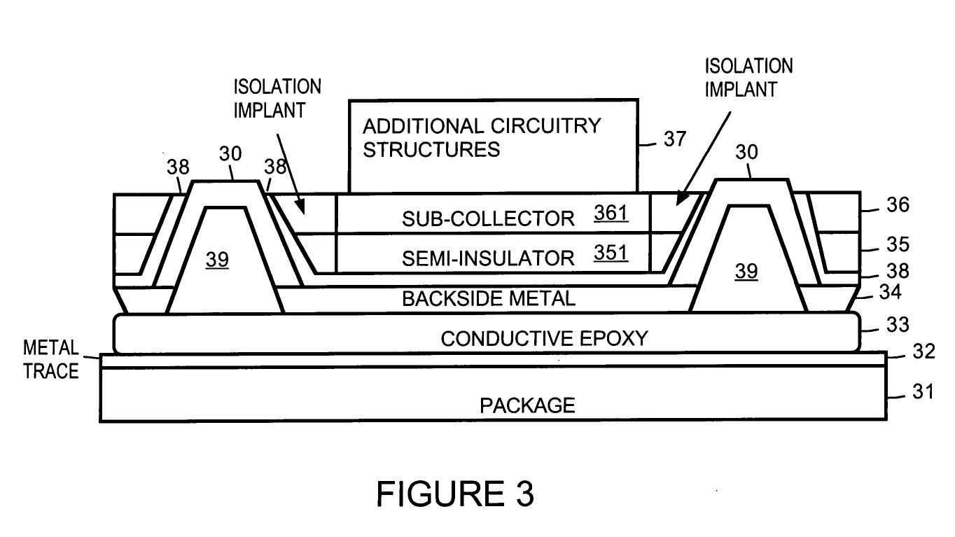

FIG. 3 illustrates an alternative embodiment of the present invention. In FIG. 3, a package 31 has a metal trace 32. Metal trace 32 is, for example, composed of gold, copper or some other metal.

A substrate includes a semi-insulating layer 35. A sub-collector is defined by a layer 36. For example, semi-insulating layer 35 is composed of gallium-arsenide (GaAs). Alternatively, semi-insulating layer 25 can be composed of indium-phosphide (InP) or any other substrate where oscillatory leakage currents might occur. Sub-collector layer 36 is highly doped for use as a sub-collector region of, for example, a bipolar transistor. Additional circuitry structures 37 are arranged over sub-collector layer 36, dependent upon implementation of a desired circuit functionality. For example, the additional circuitry structures can include one or more base regions, one or more collector regions and one or more emitter region when a bipolar transistor is implemented. Isolation implants are used to isolate a sub-collector region 361 and a semi-insulator region 351 directly below additional circuitry structures 37. Backside metal 34 is placed on a backside of the substrate. Via regions 39 provide connection to backside metal 34 through metal regions 30.

A conductive epoxy 33 is used to attach package 31 to backside metal 34. Conductive epoxy 33 electrically connects metal trace 32 to backside metal 34. In order to eliminate LFO generation in semi-insulator region 351, an insulator 38 is located between semi-insulating layer 35 and backside metal 34. As shown in FIG. 3, insulator 38 extends up sidewalls of via regions 39, isolating metal regions 30 from semi-insulating layer 35 and sub-collector layer 36. For example, insulator 38 is composed of silicon nitride, silicon oxide, or some other insulating material deposited on the backside of the wafer. As a result, sub-collector region 361 and semi-insulator region 351 float at the collector voltage. This eliminates the electric field across semi-insulator region 351 and the LFO current generated in semi-insulator region 351.

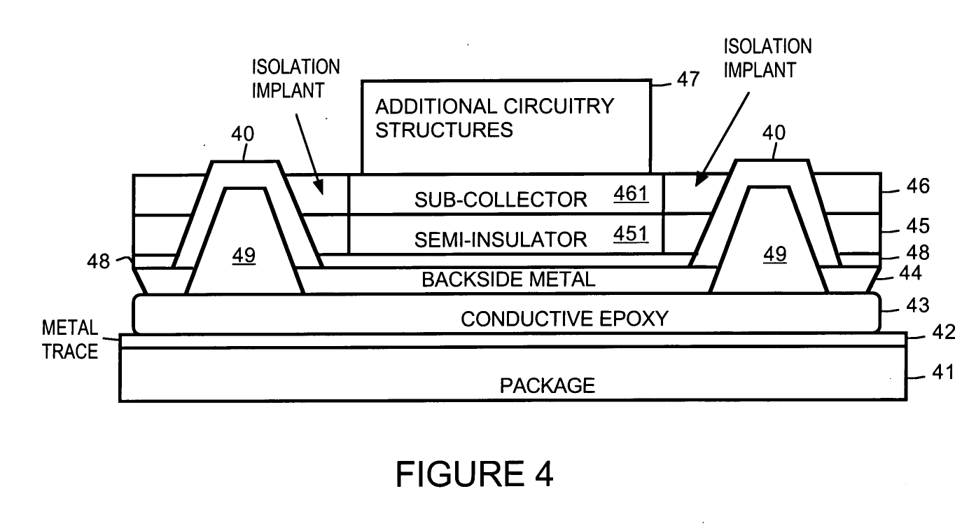

FIG. 4 illustrates an alternative embodiment of the present invention. In FIG. 4, a package 41 has a metal trace 42. Metal trace 42 is, for example, composed of gold, copper or some other metal.

A substrate includes a semi-insulating layer 45. A sub-collector is defined by a layer 46. For example, semi-insulating layer 45 is composed of Gallium-Arsenide. Sub-collector layer 46 is highly doped for use as a sub-collector region of, for example, a bipolar transistor. Additional circuitry structures 47 are arranged over sub-collector layer 46, dependent upon implementation of a desired circuit functionality. For example, the additional circuitry structures can include one or more base regions, one or more collector regions and one or more emitter region when a bipolar transistor is implemented. Isolation implants are used to isolate a sub-collector region 461 and a semi-insulator region 451 directly below additional circuitry structures 47. Backside metal 44 is placed on a backside of the substrate. Via regions 49 provide connection to backside metal 44 through metal regions 40.

A conductive epoxy 43 is used to attach package 41 to backside metal 44. Conductive epoxy 43 electrically connects metal trace 42 to backside metal 44. In order to eliminate LFO current generation in semi-insulator region 451, an insulator 48 is placed between semi-insulating layer 45 and backside metal 44. As shown in FIG. 4, insulator 48 does not extend up sidewalls of via regions 49. This makes this circuit easier to fabricate than the circuit shown in FIG. 3. For example, insulator 48 is composed of silicon nitride, silicon oxide, or some other insulating material deposited on the backside of the wafer. As a result, sub-collector region 461 and semi-insulator region 451 float at the collector voltage. This eliminates the electric field across semi-insulator region 451 and thus the LFO current generated in the semi-insulator region 451.

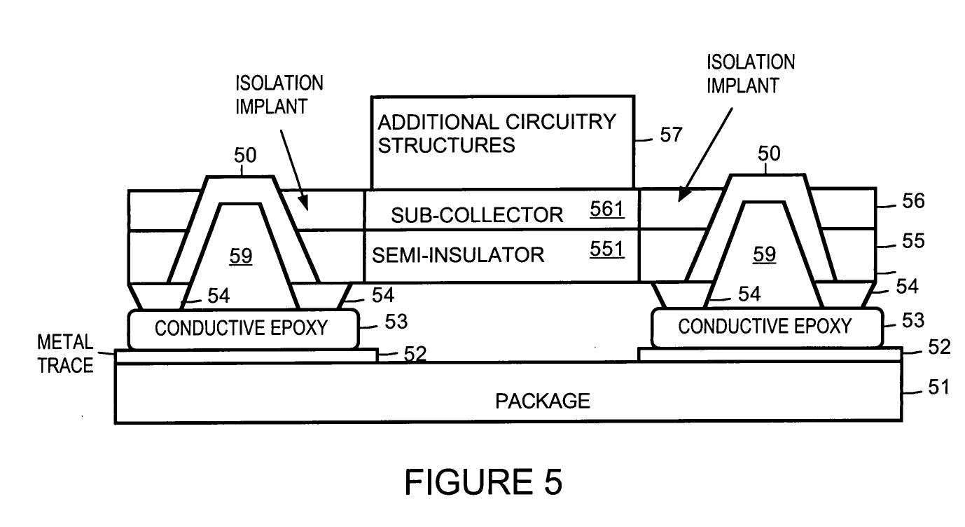

FIG. 5 illustrates an alternative embodiment of the present invention. In FIG. 5, a package 51 has a metal trace 52. Metal trace 52 is, for example, composed of gold, copper or some other metal.

A substrate includes a semi-insulating layer 55. A sub-collector is defined by a layer 56. For example, semi-insulating layer 55 is composed of Gallium-Arsenide. Sub-collector layer 56 is highly doped for use as a sub-collector region of, for example, a bipolar transistor. Additional circuitry structures 57 are arranged over sub-collector layer 56, dependent upon implementation of a desired circuit functionality. For example, the additional circuitry structures can include one or more base regions, one or more collector regions and one or more emitter region when a bipolar transistor is implemented. Isolation implants are used to isolate a sub-collector region 561 and a semi-insulator region 551 directly below additional circuitry structures 57. Backside metal 54 is placed on a backside of the substrate. Via regions 59 provide connection to backside metal 54 through metal regions 50.

A conductive epoxy 53 is used to attach package 51 to backside metal 54. Conductive epoxy 53 electrically connects metal trace 52 to backside metal 54. In order to eliminate LFO current generation in semi-insulator region 551, backside metal 54 is etched off under semi-insulator regions 551. As a result sub-collector region 561 and semi-insulator region 551 float at the collector voltage. This eliminates the electric field across semi-insulator region 551 and thus the LFO current generated in semi-insulator region 551.

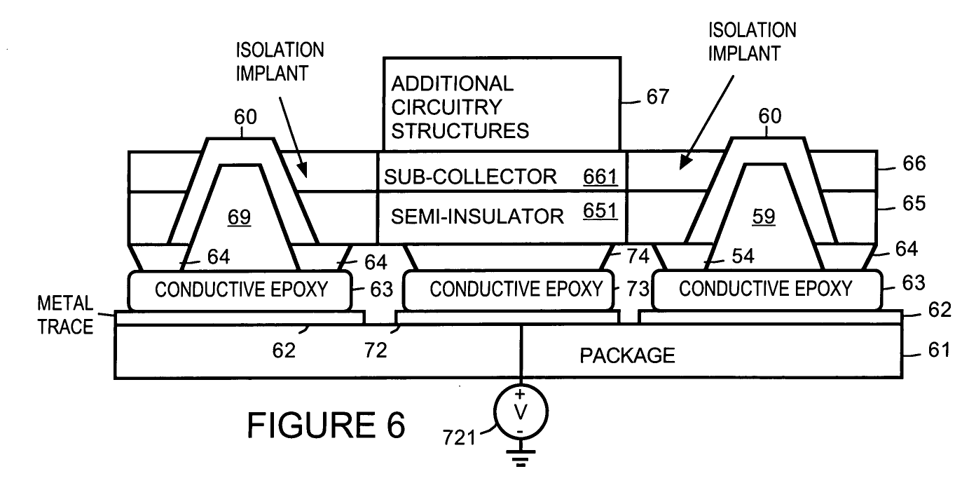

FIG. 6 illustrates an alternative embodiment of the present invention. In FIG. 6, a package 61 has a metal trace 62. Metal trace 62 is, for example, composed of gold, copper or some other metal.

A substrate includes a semi-insulating layer 65. A sub-collector is defined by a layer 66. For example, semi-insulating layer 65 is composed of Gallium-Arsenide. Sub-collector layer 66 is highly doped for use as a sub-collector region of, for example, a bipolar transistor. Additional circuitry structures 67 are arranged over sub-collector layer 66, dependent upon implementation of a desired circuit functionality. For example, the additional circuitry structures can include one or more base regions, one or more collector regions and one or more emitter region when a bipolar transistor is implemented. Isolation implants are used to isolate a sub-collector region 661 and a semi-insulator region 651 directly below additional circuitry structures 67. Backside metal 64 is placed on a backside of the substrate. Via regions 69 provide connection to backside metal 64 through metal regions 60.

A conductive epoxy 63 is used to attach package 61 to backside metal 64. Conductive epoxy 63 electrically connects metal trace 62 to backside metal 64. In order to eliminate LFO current generation in semi-insulator region 651, backside metal 64 is etched so that via metal regions 60 can be biased at a different voltage than semi-insulator region 651. As shown in FIG. 6, semi-insulator region 651 is electrically connected to a trace portion 72 through a backside metal portion 74 and a conductive epoxy region 73. An external voltage supply 721 places a bias on metal trace portion 72. The bias is kept close to the voltage potential on sub-collector region 761, thereby eliminating LFOs caused by electric field across semi-insulator region 751.

The foregoing discussion discloses and describes merely exemplary methods and embodiments of the present invention. As will be understood by those familiar with the art, the invention may be embodied in other specific forms without departing from the spirit or essential characteristics thereof. For example, several illustrative methods were given for controlling the bias and/or electric field of the semi-insulator substrate; however, as will be understood by persons of ordinary skill in the art, there are many other ways to control the bias and/or electric field of the semi-insulator substrate. Also, the embodiments of the invention were illustrated primarily showing how LFO currents can be eliminated when GaAs is used as a semi-insulating layer. Nevertheless, if LFO currents appear in other semi-insulating layers, such as semi-insulating layers composed of InP, embodiments of the invention are equally useful in eliminating the LFO currents. Accordingly, the disclosure of the present invention is intended to be illustrative, but not limiting, of the scope of the invention, which is set forth in the following claims.

We claim:

1. A method for eliminating low frequency oscillations in a circuit comprising:
forming a sub-collector region over a semi-insulator region;
forming bipolar transistor circuitry over the sub-collector region, the bipolar transistor circuitry including a collector; and,
controlling voltage at the semi-insulator region so that voltage at the semi-insulator region is approximately equal to voltage on the collector.

2. A method as in claim 1 wherein the bipolar transistor circuitry implements a heterojunction bipolar transistor.

3. A method as in claim 1 wherein the semi-insulator region is composed of one of the following:
gallium-arsenide;
indium phosphide.

4. A method as in claim 1 wherein controlling voltage at the semi-insulator region is accomplished by connecting the circuit to a package using insulating epoxy so that there is minimal electric field between the semi-insulator region and the package.

5. A method as in claim 1 wherein controlling voltage at the semi-insulator region is accomplished by connecting the circuit to a package using conductive epoxy so that there can be minimal current flow from the semi-insulator region to a metal trace within the package, wherein the metal trace is biased to a voltage approximately equal to the voltage on the collector.

6. A method as in claim 1 wherein controlling voltage at the semi-insulator region is accomplished by placing an insulating region between the semi-insulator region and backside metal to electrically insulate the semi-insulator region from the backside metal.

7. A method as in claim 1 wherein controlling voltage at the semi-insulator region is accomplished by placing an insulating region between the semi-insulator region and backside metal to electrically insulate the semi-insulator region from the backside metal, the insulating region also extending up sidewalls of vias placed within the circuit.

8. A method as in claim 1 wherein controlling voltage at the semi-insulator region is accomplished by etching backside metal of the circuit so that no backside metal is contact with the semi-insulator region.

9. A method as in claim 1 wherein controlling voltage at the semi-insulator region is accomplished by etching backside metal of the circuit so that a backside metal portion in contact with the semi-insulator region is not in contact with backside metal in contact with vias within the circuit, wherein the backside metal portion in contact with the semi-insulator region is biased to a voltage approximately equal to the voltage on the collector.

10. A circuit comprising;
bipolar transistor circuitry, the bipolar transistor circuitry including a collector;
a sub-collector region formed under bipolar transistor circuitry, the bipolar transistor circuitry including a collector; and,
a semi-insulator region formed under the sub-collector region;
wherein voltage at the semi-insulator region is controlled so that voltage at the semi-insulator region is approximately equal to voltage on the collector.

11. A circuit as in claim 10 wherein the bipolar transistor circuitry implements a heterojunction bipolar transistor.

12. A circuit as in claim 10 wherein the semi-insulator region is composed of one of the following:
gallium-arsenide;
indium phosphide.

13. A circuit as in claim 10 wherein controlling voltage at the semi-insulator region is accomplished by the circuit being connected to a package through insulating epoxy so that there is minimal electric field between the semi-insulator region and the package.

14. A circuit as in claim 10 wherein controlling voltage at the semi-insulator region is accomplished by the circuit being connected to a package through conductive epoxy so that there can be minimal current flow from the semi-insulator region to a metal trace within the package, wherein the metal trace is biased to a voltage approximately equal to the voltage on the collector.

15. A circuit as in claim 10 wherein controlling voltage at the semi-insulator region is accomplished by an insulating region being situated between the semi-insulator region and backside metal of the circuit to electrically insulate the semi-insulator region from the backside metal.

16. A circuit as in claim 10 wherein controlling voltage at the semi-insulator region is accomplished by an insulating region being situated between the semi-insulator region and backside metal of the circuit to electrically insulate the semi-insulator region from the backside metal, the insulating region also extending up sidewalls of vias placed within the circuit.

17. A circuit as in claim 10 wherein controlling voltage at the semi-insulator region is accomplished by backside metal of the circuit being etched so that no backside metal is contact with the semi-insulator region.

18. A circuit as in claim 10 wherein controlling voltage at the semi-insulator region is accomplished by backside metal of the circuit being etched so that a backside metal portion in contact with the semi-insulator region is not in contact with backside metal in contact with vias within the circuit, wherein the backside metal portion in contact with the semi-insulator region is biased to a voltage approximately equal to the voltage on the collector.

19. A method for eliminating low frequency oscillations in a bipolar transistor circuit comprising:
forming a sub-collector region of the bipolar transistor on a semi-insulator region portion of a substrate, the sub-collector being formed under a collector region of the bipolar transistor; and,
controlling voltage at the semi-insulator region so that voltage at the semi-insulator region is approximately equal to voltage on the collector region.

20. A method as in claim 19 wherein the semi-insulator region is composed of one of the following:
gallium-arsenide;
indium phosphide.
